(19) United States
(12) Patent Application Publication
(10) Pub. No.: US 2016/0276428 A1
(43) Pub. Date: Sep. 22, 2016

(54) HIGH-VOLTAGE TRANSISTOR DEVICE

(71) Applicant: GLOBALFOUNDRIES Inc., Grand Cayman (KY)

(72) Inventors: Juergen Faul, Dresden (DE); Peter Javorka, Radeburg (DE)

(21) Appl. No.: 14/658,361

(22) Filed: Mar. 16, 2015

(51) Int. Cl. H01L 29/06; H01L 29/66; H03K 17/687; H01L 21/762; H01L 21/28; H01L 29/78; H01L 29/423

(52) U.S. Cl. CPC H01L 29/0649; H01L 29/78; H01L 29/66568; H01L 29/0653; H01L 29/42356; H01L 21/76283; H01L 21/28008; H03K 17/687

(57) ABSTRACT

A semiconductor device is provided including a substrate, a buried oxide layer formed over the substrate, a semiconductor layer formed over the buried oxide layer, and a transistor device including a gate electrode, a gate insulation layer and a channel region, wherein the gate insulation layer comprises a part of the buried oxide layer.

### BACKGROUND OF THE INVENTION

1. Field of the Invention

Generally, the subject matter disclosed herein relates to integrated circuits, and, more particularly, to transistor devices allowing for a high-voltage operation.

2. Description of the Related Art

Integrated circuits formed on semiconductor wafers typically include a large number of circuit elements, which form an electric circuit. In addition to active devices such as, for example, field effect transistors and/or bipolar transistors, integrated circuits can include passive devices such as resistors, inductors and/or capacitors. In particular, during the fabrication of complex integrated circuits using CMOS technology, millions of transistors, i.e., N-channel transistors and P-channel transistors, are formed on a substrate including a crystalline semiconductor layer.

A MOS transistor, for example, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed near the channel region and separated therefrom by a thin insulating layer. The conductivity of the channel region, upon formation of a conductive channel due to the application of an appropriate control voltage to the gate electrode, depends on, among other things, the dopant concentration, the mobility of the majority charge carriers and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the overall conductivity of the channel region substantially determines the performance of the MOS transistors.

For rectifying and/or switching applications, high-voltage transistors are needed. The development of single chip processes for integrating power switches with control circuitry is a major trend in the field of power IC development. The LDMOS (lateral double diffusion MOS) process in particular is currently being applied to manufacture monolithic ICs. For example, LDMOS FETs are key components of RF power amplifiers used in base stations for personal communication systems (for example, GSM, EDGE, etc.). High breakdown-voltages are most important advantages of LDMOS FETs.

As a device of MOSFET variety, an LDMOS FET uses an inversion channel at the silicon-oxide interface. The inversion channel is induced under the gate by positive gate potential. Under practically relevant conditions, the inversion layer only exists over the laterally diffused P-well, which is sometimes called depletion stopper. As the electrons leave the region over the stopper, they are picked up by the electric field due to positive drain bias and abandon the inversion channel going deeper into the bulk. The effective gate length defines the lateral extension of the stopper layer. It may be, therefore, shorter than the physical length of the gate electrode. The LDMOS process, typically, involves performing planar diffusion on the surface of a semiconductor substrate to form a main current path oriented in the lateral direction. Since the lateral MOSFET is manufactured using a typical IC process, the control circuit and the lateral power MOSFET can be integrated onto a monolithic power IC. An LDMOS process using a reduced surface electric field (RESURF) technique with a low thickness EPI or N-well can achieve a high voltage with low on-resistance. A variety of LDMOS designs have been proposed for integrating control circuitry with power switches.

FIG. 1 illustrates a typical example of a bulk LDMOS transistor device. The shown LDMOS FET comprises a P-doped substrate 1, for example, a substrate comprising silicon. An N-doped drift region 2 is formed over the substrate 1. Moreover, the shown LDMOS FET comprises a laterally diffused P-doped well 3 and an N⁺-doped region 4. Whereas, in particular LDMOS devices known in the art, P-doped wells may be neighbored by P-doped sinkers connecting a source with highly doped substrates; in the shown example, no P-doped sinker is provided. A gate 5, for example, a silicided polysilicon gate, is formed to overlap at least the P-doped well 3. A drain 6 is formed over another N⁺-doped region 7. The drift region 2 is provided for reducing a voltage drop between the gate and drain junctions. A lowly doped drain extension region may connect the N⁺-doped region 7 below the drain 6 and the P-doped well 3 within the drift region 2. The lowly doped drain extension region may be uniformly doped or comprise a step-wise profile resulting in two adjacent lowly doped regions.

However, LDMOS FETs as the one described with reference to FIG. 1 only allow for relatively high drain voltages. Limited gate voltages implied by the LDMOS design restrict high-frequency applications, in principle. In view of this, the present disclosure relates to transistor devices and techniques for forming transistor devices allowing for high-frequency, high-voltage operation with high reliability and improved design options as compared to the art.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to semiconductor devices and methods for fabricating the same, wherein enhanced transistor performance may be obtained for N-channel transistors and P-channel transistors on the basis of silicon-on-insulator (SOI) techniques.

One illustrative semiconductor device disclosed herein includes a substrate, a buried oxide layer formed over the substrate, a semiconductor layer formed over the buried oxide layer and a transistor device. The transistor device includes a gate electrode, a gate insulation layer and a channel region. The gate insulation layer (gate dielectric) comprises a part of the buried oxide layer. The transistor device may be an N-channel or a P-channel TFT.

One illustrative method of forming a semiconductor device disclosed herein includes providing a silicon-on-insulator (SOI) wafer comprising a substrate, a buried oxide layer and a semiconductor layer and forming a transistor device in and on the wafer. The formation of the transistor device includes forming a gate electrode in the substrate by doping the substrate and forming a gate insulation layer from the buried oxide layer.

According to another example, a method of forming a semiconductor device is provided included providing a silicon-on-insulator (SOI) wafer comprising a substrate, a buried oxide layer and a semiconductor layer, and forming a transistor device in and on the wafer. The formation of the transistor device includes forming a gate electrode in the semiconductor layer and forming a gate insulation layer from the buried oxide layer.

The thus manufactured or provided transistor may be used as a switching device in high-frequency applications. Thus, a method of driving a transistor device as a switch is also provided, wherein the transistor device is formed in and on an SOI wafer and comprises a gate electrode and a part of a buried oxide layer of the SOI wafer as a gate dielectric, comprising applying an electrical voltage of more than 5 V, for example, more than 8 V, to the gate electrode.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates an LDMOS FET of the art;

FIGS. 2a-2c illustrate a process of forming a semiconductor device comprising a transistor device with a gate insulation layer formed from part of a buried oxide layer of an SOI wafer and with a gate electrode formed in the substrate of the SOI wafer, according to an illustrative example of the present invention;

FIGS. 3a-3c illustrate a process of forming a semiconductor device comprising a transistor device with a gate insulation layer formed from part of a buried oxide layer of an SOI wafer and with a gate electrode formed in the semiconductor layer of the SOI wafer, according to an illustrative example of the present invention; and

FIG. 4 illustrates an exemplary process flow for the manufacture of an SOI wafer suitable for the formation of a semiconductor device according to an example of the present invention.

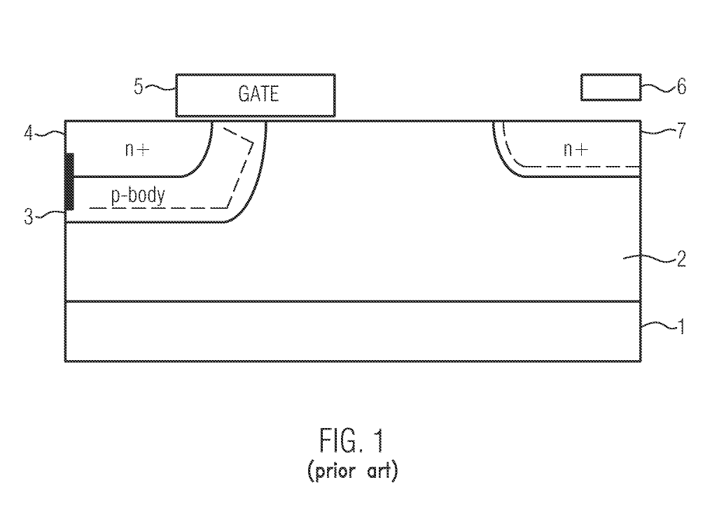

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

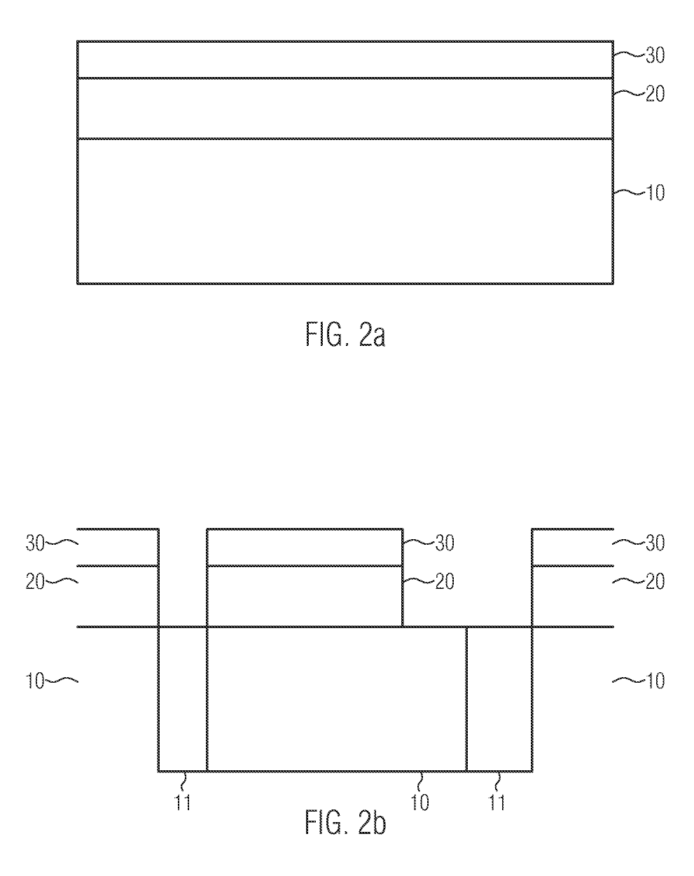

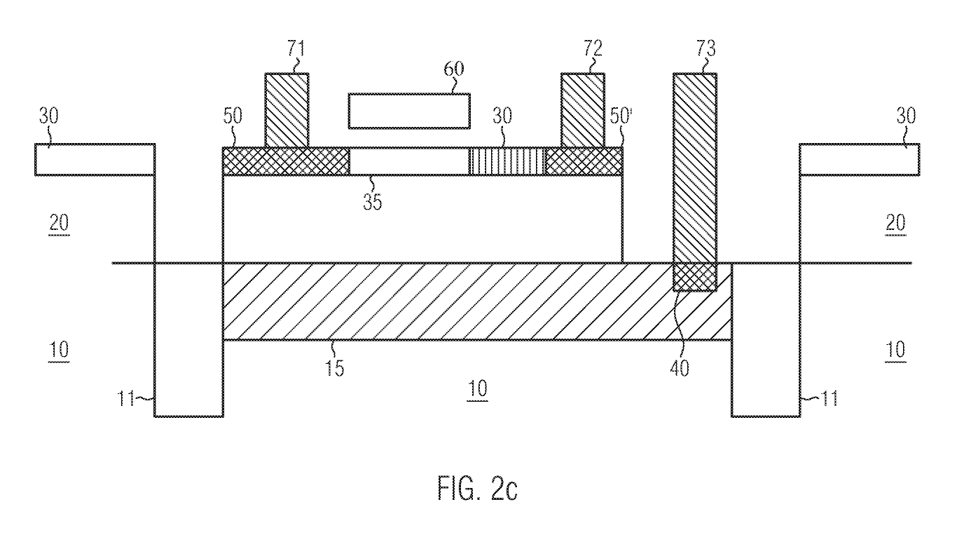

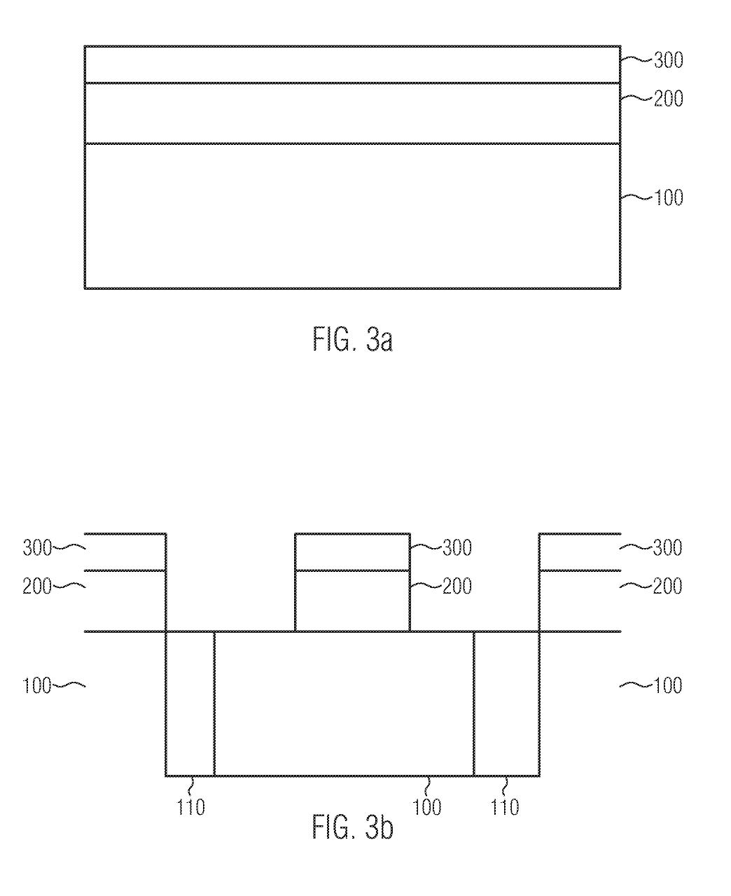

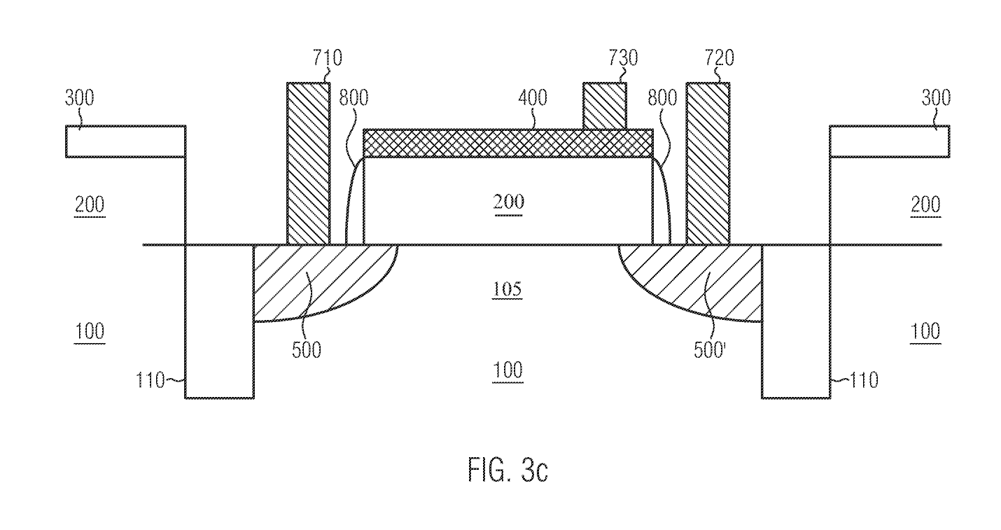

Generally, it is described how to manufacture a semiconductor device with a transistor device allowing for applying relatively high voltages, for example, voltages of some 5 to 10 V, to the gate electrode of the transistor device. With reference to FIGS. 2a-2c and 3a-3c, further illustrative embodiments will now be described in more detail.

As shown in FIG. 2a, an SOI wafer is provided comprising a substrate 10, a buried oxide (BOX) layer 20 and a semiconductor layer 30. The semiconductor layer 30 may comprise a significant amount of silicon due to the fact that semiconductor devices of high integration density may be formed in volume production on the basis of silicon due to the enhanced availability and the well-established process techniques developed over the last decades. However, any other appropriate semiconductor materials may be used, for instance, a silicon-based material containing other iso-electronic components, such as germanium, carbon, silicon/germanium, silicon/carbon, other II-VI or III-V semiconductor compounds and the like.

The BOX layer 20 may comprise silicon (di)oxide or a borosilicate glass or a borophosphosilicate glass (BPSG). The BOX layer may be composed of different layers and one of the different layers may comprise BPSG or an SiO₂ compound comprising boron or phosphorus. The substrate 10 may be a semiconductor substrate, for example, a silicon substrate, in particular, a single crystal silicon substrate. Other materials may be used to form the semiconductor substrate 10 such as, for example, germanium, silicon germanium, gallium phosphate, gallium arsenide, etc. The thickness of the semiconductor layer 30 may lie in the range of 5-30 nm, in particular, 5-15 nm, and the thickness of the BOX layer 20 may lie in the range of 10-50 nm, in particular, 10-30 nm and, more particularly, 15-25 nm.

From the wafer shown in FIG. 2a, the configuration shown in FIG. 2b may be formed by standard lithography techniques comprising masking and etching. In particular, shallow trench isolation (STI) regions 11 are formed in order to electrically isolate the transistor device to be formed from other electric components of an IC formed on the wafer. The STI regions 11 may be formed by etching openings in the substrate 10 and filling the opening by some insulating material, for example, some oxide material.

FIG. 2c shows an example of a transistor device that may be formed starting from the configuration shown in FIG. 2b. In the substrate 10, an N-well—back gate 15 may be formed by doping. Particularly, the back gate electrode 15 formed in the substrate may comprise an N⁺ doped contact region 40. Formation of the N⁺ doped contact region 40 may comprise epitaxial growth or via extension implant. The N⁺ doped contact region 40 may also be formed during the process of forming a source region 50 and a drain region 50′ of the transistor. The source and drain regions 50 and 50′ are formed in the semiconductor layer 30 by N⁺ doping as known in the art. Silicidation of the source and drain regions 50 and 50′ may be carried out if desired. A mask layer (dummy gate) may be formed over the semiconductor layer 30 when forming the source and drain regions 50 and 50′ and the masked portion of the semiconductor layer 30 forms the channel region 35 of the transistor device. The source 50, drain 50′ and gate 15 are electrically contacted by contacts 71, 72 and 73, respectively.

The device shown in FIG. 2c allows for high-voltages applied to both the gate 15 and the drain 50′ or the gate 15 only. An operation voltage (switching voltage) of 8 to 10 V, or some 10 to 20 V or more, may be achieved, in principle. Different from the art, a relative high voltage (some 10 V, for example) can be applied to the gate electrode. If a high voltage is also to be applied to the drain, an N⁻-doped drift region may be implanted in the semiconductor layer 30 between the drain 50′ and the channel region 35 of the transistor device. It should also be noted that the dummy gate 60 may be biased by connection to ground or wiring to the source 50.

The transistor device formed in accordance with FIG. 2c can also be realized in the context of a P-channel LDMOS transistor wherein the P-well represents the back gate and an additional deep N-well is formed below the P-well back gate.

Another example of the manufacture of a semiconductor device comprising a transistor device according to the present invention is illustrated in FIGS. 3a-3c. Similar to the previously described example, an SOI wafer is provided comprising a substrate 100, a buried oxide (BOX) layer 200 and a semiconductor layer 300 (see FIG. 3a). Any appropriate semiconductor materials may be used for the semiconductor layer 300, for instance, a silicon-based material containing other iso-electronic components, such as germanium, carbon, silicon/germanium, silicon/carbon, other II-VI or III-V semiconductor compounds and the like.

Again, the BOX layer 200 may comprise silicon (di)oxide. The substrate 100 may be a semiconductor substrate, for example, a silicon substrate, in particular, a single crystal silicon substrate. Other materials may be used to form the semiconductor substrate 100 such as, for example, germanium, silicon germanium, gallium phosphate, gallium arsenide, etc. The thickness of the semiconductor layer 300 may lie in the range of 5-30 nm, in particular, 5-15 nm, and the thickness of the BOX layer 20 may lie in the range of 10-50 nm, in particular, 10-30 nm and, more particularly, 15-25 nm.

From the wafer shown in FIG. 3a, the configuration shown in FIG. 3b may be formed by standard lithography techniques comprising masking and etching. In particular, shallow trench isolation (STI) regions 110 are formed in order to electrically isolate the transistor device to be formed from other electric components of an IC. The STI regions 110 may be formed by etching openings in the substrate 100 and filling the opening with some insulating material, for example, some oxide material.

In the substrate 100, some appropriate well implant may be performed. Moreover, as shown in FIG. 3c, source and drain regions 500 and 500′ may be formed by appropriate doping processes known in the art. The source and drain regions 500 and 500′ may be formed by a self-aligned implant when using the etching mask used for the etching process carried out to obtain the configuration shown in FIG. 3b from the wafer illustrated in FIG. 3a as an implant mask for forming the source/drain regions 500, 500′. The source and drain regions 500 and 500′ may comprise source and drain extension regions and/or may be silicided if desired.

Different from the example shown in FIG. 2c, the channel region 105 of the transistor device is formed in the substrate 100. Similar to the example shown in FIG. 2c, the BOX layer 200 functions as a gate insulation layer (gate dielectric). The part of the semiconductor layer 300 formed over the BOX layer 200 and above the channel region 105 is used to form a gate electrode 400 of the transistor device.

The gate electrode 400 may be formed by appropriately doping the semiconductor layer 300 or it may be formed as a fully silicided gate electrode, for instance, a fully silicided polysilicon gate electrode. The gate electrode 400 may comprise a metal-containing layer formed on the dielectric layer. The metal-containing layer may comprise at least one of titanium nitride (TiN), tantalum nitride (TaN), tantalum (Ta), tungsten (W), for example. The metal-containing layer may be relatively thin with a thickness below 50 nm, in particular, below 20 nm. The gate electrode material may comprise a semiconductor layer, for example, comprising silicon, above the metal-containing layer. The semiconductor layer of the gate electrode material may comprise un-doped polycrystalline silicon.

The source 500, drain 500′ and gate 400 are electrically contacted by contacts 710, 720 and 730, respectively. It is noted that N⁺ contact regions for contacting the source/drain and gate electrodes may be formed. The formation of these N⁺ contact regions may comprise implantation and/or epitaxial growth. The configuration shown in FIG. 3c allows for applying relatively high voltages (for example, some 10 V) to the gate electrode 400. However, the breakdown voltage (and, thus, the operation voltage) depends on the material chosen for the BOX layer 200. Moreover, relatively high voltages (for example, some 10 V) may be applied to the drain electrode 500′. In this case, it might be considered forming a drift region between the drain 500′ and the central channel region 105. However, relatively low dopant doses for the source and drain regions 500 and 500′ with dopants of a density of about 10¹³/cm² to 10¹⁴/cm² in a lowly doped well (about 10¹⁷/cm²) result in a relatively high breakdown voltage (and, thereby, operation voltage) that does allow for omitting the formation of an additional drift region in the substrate 100.

If considered appropriate, sidewall spacers 800 may be employed for the doping processes used to form the drain and source regions 500 and 500′. Formation of the sidewall spacers 800 after performing the etching process based on an etching mask, for example, an NO mask, used for etching the wafer of FIG. 3a, thus, allows for tuning the source/drain 500, 500′ lateral dimensions.

It should be noted that both the semiconductor device of the example illustrated in FIG. 2c and the semiconductor device of the example illustrated in FIG. 3c can be manufactured as fully depleted SOI devices. Moreover, the shown semiconductor devices may be formed in the context of ultra-thin BOX (UTBOX) technologies characterized by thicknesses of the BOX layers of less than 50 nm, or even less than 30 nm. Hot carrier injection may be controlled by adjusting the gate lengths appropriately and by junction formation.

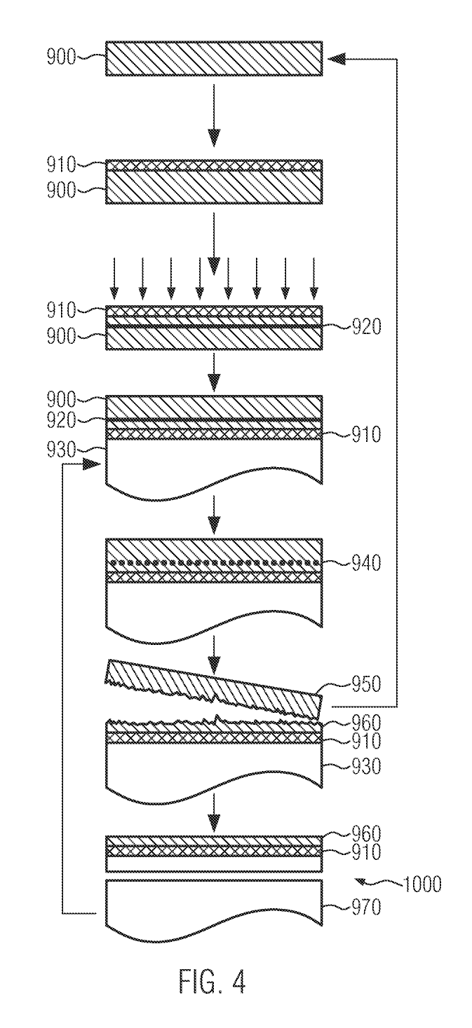

According to the disclosure, the BOX layer of an SOI wafer is used as a gate dielectric of a transistor device. Therefore, it is necessary that the quality of the SOI wafer, in particular, the quality of the BOX layer, is rather high. A high-quality SOI wafer may be provided by means of the SMARTCUT® technique. FIG. 4 illustrates an exemplary process flow for the manufacturing of an SOI wafer. A semiconductor wafer 900 is provided and surface oxidation results in formation of an oxide layer 910. The semiconductor wafer 900 may comprise silicon and the oxide layer 910 may comprise silicon (di)oxide. A weakened layer 920 is formed by ion implantation, for example, hydrogen implantation, through the oxide layer. The weakened layer 920 is provided in order to facilitate detachment of part of the semiconductor wafer 900. Thereafter, the SOI wafer 900 with the oxide layer 910 and weakened layer 920 is bonded to a handle wafer 930 by the oxide layer 910. The handle wafer 930 may also comprise an oxide layer to be bonded to the oxide layer 910 of the semiconductor wafer 900.

After bonding of the semiconductor wafer 900 and the handle wafer 930, an anneal treatment is performed to generate bubbles 940 in the weakened layer 920. The bubble formation facilitates breakage at the weakened layer 920. The separated part 950 of the semiconductor wafer can be re-used for the formation of another SOI wafer. The surface of the resulting semiconductor layer 960 may be treated by chemical mechanical polishing to provide the semiconductor layer 960 of an SOI wafer 1000. Eventually, the SOI wafer 1000 results by cutting the handle wafer 930 as illustrated at the bottom of FIG. 4. The remainder 970 of the handle wafer 930 can be re-used for the formation of another SOI wafer.

The process flow illustrated in FIG. 4 may be supplemented by an additional heat treatment of the oxide layer 910, for example, after breakage at the weakened layer 920 or before or after cutting the handle wafer 930. By the additional heat treatment, the quality of the (buried) oxide layer 910 of the resulting SOI wafer 1000, for example, in terms of homogeneity of the oxide material, may be improved. Alternatively or additionally, a heat treatment of the wafer provided as illustrated in FIGS. 2a or 3a may be performed before the processing illustrated in FIG. 2b for the same purpose of enhancing the quality of the BOX layer 20 of FIGS. 2a to 2c or BOX layer 200 of FIGS. 3a to 3c, respectively.

As a result, the present application provides a semiconductor device and manufacturing techniques for such a semiconductor device wherein the semiconductor device comprises a transistor with a gate insulation layer made of the BOX layer of an SOI wafer. Thereby, supply of relatively high voltages to the gate electrode of the transistor during operation is made possible without running the risk of damaging the transistor.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

1. A semiconductor device, comprising:
a substrate;
a buried oxide layer formed over said substrate;
a semiconductor layer formed over said buried oxide layer; and
a transistor device comprising a gate electrode formed in said substrate below said buried oxide layer, a channel region formed in said semiconductor layer, a source region formed in said semiconductor layer adjacent a first of said channel region, a drift region formed in said semiconductor layer adjacent a second side of said channel region, and a drain region formed in said semiconductor layer adjacent said drift region.

2-5. (canceled)

6. The semiconductor device of claim 1, further comprising shallow trench isolation regions adjacent to said gate electrode.

7-10. (canceled)

11. The semiconductor device of claim 1, wherein said buried oxide layer has a thickness of about 20-30 nm and said semiconductor layer has a thickness of about 5-20 nm.

12. A method of forming a semiconductor device, comprising
providing a silicon-on-insulator (SOI) wafer comprising a substrate, a buried oxide layer and a semiconductor layer;
forming a transistor device in and on said wafer, comprising:
forming a gate electrode in said substrate below a channel region defined in said semiconductor layer;
forming a gate insulation layer from said buried oxide layer;
forming source and drain regions of said transistor device in said semiconductor layer adjacent said channel region; and
forming a drift region in said semiconductor layer between said channel region and said drain region.

13. (canceled)

14. The method of claim 12, further comprising forming shallow trench isolation regions adjacent to said gate electrode.

15-19. (canceled)

20. A method of driving a transistor device as a switch, wherein said transistor device is formed in and on an SOI wafer and comprises a gate electrode defined below a part of a buried oxide layer of said SOI wafer, source and drain regions defined in a semiconductor layer disposed above said buried oxide layer, and a drift region defined in said semiconductor layer between said channel region and said drain region, comprising applying an electrical voltage of more than 5 V to said gate electrode.

21. The method of claim 12, wherein forming said gate electrode comprises doping said substrate in a region disposed below said channel region.

22. The method of claim 12, wherein forming said source and drain regions comprises forming a dummy gate above said semiconductor layer and doping said semiconductor layer using said dummy gate as a mask.

23. The method of claim 22, wherein said channel region is defined beneath said dummy gate.

24. A method, comprising:
providing a silicon-on-insulator (SOI) wafer comprising a substrate, a buried oxide layer and a semiconductor layer;
forming a gate electrode in said substrate below said buried oxide layer;
forming a dummy gate above said semiconductor layer and above said gate electrode;
forming source and drain regions of said transistor device in said semiconductor layer adjacent a channel region defined in said semiconductor layer beneath said dummy gate; and
forming a drift region in said semiconductor layer between said channel region and said drain region.

25. The method of claim 24, further comprising forming shallow trench isolation regions in said substrate adjacent to said gate electrode.

26. The method of claim 24, wherein forming said gate electrode comprises doping said substrate.
